(19) United States
(12) Patent Application Publication
(10) Pub. No.: US 2008/0179605 A1
(43) Pub. Date: Jul. 31, 2008

(54) NITRIDE SEMICONDUCTOR LIGHT EMITTING DEVICE AND METHOD FOR FABRICATING THE SAME

(76) Inventors: Yuji TAKASE, Osaka (JP); Tetsuzo Ueda, Osaka (JP); Tsuyoshi Tanaka, Osaka (JP); Daisuke Ueda, Osaka (JP)

Correspondence Address: MCDERMOTT WILL & EMERY LLP, 600 13TH STREET, NW, WASHINGTON, DC, 20005-3096, US

(21) Appl. No.: 11/937,234

(22) Filed: Nov. 8, 2007

(30) Foreign Application Priority Data
Jan. 29, 2007 (JP) 2007-018484

(51) Int. Cl. H01L 33/00

(52) U.S. Cl. 257/94; 438/29; 257/E33.048

(57) ABSTRACT

A nitride semiconductor light emitting device includes: a dielectric layered film over a substrate, the dielectric layered film being formed by stacking a plurality of dielectric films having different compositions; a semiconductor thin film formed of a single crystal over the dielectric layered film; and a pn junction diode structure over the semiconductor thin film, the pn junction diode structure being formed of a nitride semiconductor.

### CROSS-REFERENCE TO RELATED APPLICATION(S)

This application claims priority under 35 U.S.C. §119(a) on Japanese Patent Application No. 2007-18484 filed on Jan. 29, 2006, the entire contents of claims, specification, and drawings of which are hereby incorporated by reference.

### BACKGROUND OF THE INVENTION

1. Field of the Invention

The present invention relates to a nitride semiconductor light emitting device applicable to a light emitting diode for emitting visible light or white light for example and to a method for fabricating the same.

2. Description of the Prior Art

A so-called nitride-based compound semiconductor (expressed by a general formula, InₓAl_{y}Ga_{1-x-y}N (where 0≦x≦1, 0≦y≦1, and x+y≦1)) typified by gallium nitride (GaN) realizes a light emitting device having a wide wavelength range including visible light such as blue light and ultraviolet light. A wide application of a light emitting diode including a nitride semiconductor is considered and examples of applications are semiconductor illuminations. The light emitting diode is expected to expand its market in future.

For crystal growth of a nitride-based semiconductor, since it is generally hard to obtain a bulk GaN crystal, a so-called heteroepitaxial growth technique is used. In the heteroepitaxial growth technique, a hetero-substrate compositionally different from the nitride-based semiconductor is used for the crystal growth. As the hetero-substrate for the crystal growth, a thermally and chemically stable single crystal sapphire (α-A₂O₃) substrate has been used to realize a high luminance light emitting diode. The sapphire substrate has a diameter, at most, of about 15.2 cm (=6 inches) for example. It is difficult to further increase the diameter of the substrate whose principal surface is a C plane (plane direction is a (0001) plane) used for the crystal growth, and it is thought that a further cost reduction is limited.

As a technique to fabricate the light emitting diode formed of the nitride-based semiconductor at lower cost, it has been reported to use a hetero-substrate made of silicon (Si) from which a large-area and high-quality substrate is available at low cost. Since silicon and the nitride-based semiconductor are greatly different in lattice constant and in thermal expansion coefficient, it has been difficult to obtain a good nitride semiconductor crystal on the substrate made of Si. However, for example, by improving a technique to grow a buffer layer provided between the hetero-substrate and the nitride semiconductor crystal, the crystalline quality of the nitride semiconductor crystal has been greatly improved and the luminance of the light emitting diode has also been improved greatly (see T. Egawa et al., IEEE Electron Device Lett., Vol. 26 (2005), for example). Moreover, epitaxial growth of a nitride semiconductor by using a Si substrate having a diameter of about 10.2 cm (=4 inches) has been reported (for example, see H. Ishikawa et al., physica status solidi (c), Vol. 0, (2003), p. 2177). It is expected that fabrication cost is greatly reduced by fabricating light emitting diodes on a Si substrate having a large diameter.

However, if a Si substrate is used as a substrate for growth of the conventional nitride semiconductor and a light emitting diode is formed on the Si substrate, a problem arises that the light power of the light emitting diode is reduced. This is because the silicon (Si) has a small band gap of 1.1 eV and blue light (wavelength is 470 nm, the energy of light corresponds to 2.64 eV) or the like is absorbed by the Si substrate.

### SUMMARY OF THE INVENTION

In view of the conventional problems, an object of the present invention is to reduce the absorption of emitted light by a substrate for crystal growth to improve light extraction efficiency of a nitride semiconductor light emitting device.

To achieve the object, according to the present invention, the nitride semiconductor light emitting device is structured such that a dielectric layered film which reflects emitted light is provided between the substrate for crystal growth and a pn junction diode structure including an active layer, and a single crystal thin film over which a nitride semiconductor can be grown is provided between the dielectric layered film and the pn junction diode structure.

Specifically, the nitride semiconductor light emitting device of the present invention includes: a dielectric layered film over a substrate, the dielectric layered film being formed by stacking a plurality of dielectric films having different compositions; a semiconductor thin film formed of a single crystal over the dielectric layered film; and a pn junction diode structure over the semiconductor thin film, the pn junction diode structure being formed of a nitride semiconductor.

According to the nitride semiconductor light emitting device of the present invention, light generated in the pn junction diode structure is reflected by the dielectric layered film upward from the substrate, and thus light extraction efficiency is improved. Therefore, it is possible to realize a higher-luminance nitride semiconductor light emitting device. Moreover, epitaxial growth of the nitride semiconductor is possible, with the semiconductor thin film formed of the single crystal being provided on the dielectric layered film.

In the nitride semiconductor light emitting device of the present invention, it is preferable that the semiconductor thin film is made of silicon, silicon carbide, or gallium nitride.

In this structure, the nitride semiconductor constituting the pn junction diode structure is epitaxially grown over the semiconductor thin film made of silicon (Si), silicon carbide (SiC), or gallium nitride (GaN) which has a high crystalline quality and is stable at a high temperature. Therefore, the crystalline quality of the nitride semiconductor is also improved, and thus it is becomes possible to realize a nitride semiconductor light emitting device having a high internal quantum efficiency.

In the nitride semiconductor light emitting device of the present invention, it is preferable that part of the dielectric layered film is formed by alternately stacking first dielectric films and second dielectric films having different compositions; and each of the first dielectric films and the second dielectric films has a film thickness of ¼ of an optical wavelength corresponding to an emitted light wavelength.

In this structure, the dielectric layered film forms a distributed Bragg reflector (DBR), and thus the dielectric layered film has a higher reflectivity. Therefore, it is suppressed that light generated by the pn junction diode structure is absorbed by the substrate, so that it is possible to realize a high-luminance nitride semiconductor light emitting device in which light extraction efficiency is improved.

In the nitride semiconductor light emitting device of the present invention, it is preferable that the dielectric layered film partially includes a glass-like film, and a temperature for liquefaction of the glass-like film is lower than a temperature for liquefaction of silicon oxide.

In this structure, since a temperature for liquefaction of the glass-like film is lower than a temperature for liquefaction of a silicon oxide (SiO₂), it is possible to relieve stress generated between the substrate and the nitride semiconductor after the epitaxial growth. This allows the film thickness of the nitride semiconductor to be increased without causing cracks in the nitride semiconductor, and thus it is possible to improve the crystalline quality of the nitride semiconductor. Therefore, it is possible to realize a higher-luminance nitride semiconductor light emitting device.

In this case, it is preferable that the glass-like film includes at least one of PSG (Phospho Silicate Glass) and BPSG (Boro Phospho Silicate Glass).

In the nitride semiconductor light emitting device of the present invention, it is preferable that the dielectric layered film has a conductive member made of a metal, the conductive member passing through the dielectric layered film and being electrically connected to the substrate.

In this structure, heat generated in the pn junction diode structure during current injection (in an operation state) is conducted via the conductive member made of a metal to the substrate and released. This suppresses a temperature rise in the pn junction diode structure, and the reduction in the internal quantum efficiency by the temperature rise less likely occurs, so that it is possible to realize a higher-power nitride semiconductor light emitting device.

It is preferable that the nitride semiconductor light emitting device of the present invention further includes a first reflection film over a surface of the pn junction diode structure opposite to the dielectric layered film, the first reflection film facing the dielectric layered film.

In this structure, the dielectric layered film and the first reflection film facing with each other with the pn junction diode structure provided therebetween form a resonator, so that it is possible to realize a surface emitting laser device which is a higher-power light emitting device.

In the nitride semiconductor light emitting device of the present invention, it is preferable that on a side surface of the dielectric layered film, electrode wiring electrically connecting the pn junction diode structure with the substrate is provided.

In this structure, if the substrate is a conductive substrate, it is possible to reduce the area of an electrode of the pn junction diode structure closer to the substrate. Therefore, it is possible to reduce the chip size of the nitride semiconductor light emitting device.

In the nitride semiconductor light emitting device of the present invention, it is preferable that the first reflection film is formed by alternately stacking third dielectric films and fourth dielectric films having different compositions, and each of the third dielectric films and the fourth dielectric films has a film thickness of ¼ of an optical wavelength corresponding to an emitted light wavelength.

In this structure, the first reflection film constitutes a DBR mirror made of a dielectric substance, and thus the first reflection film has a higher reflectivity. Therefore, it is possible to realize a nitride semiconductor surface emitting laser device having a lower oscillation threshold.

Moreover, in the nitride semiconductor light emitting device of the present invention, it is preferable that part of the first reflection film is formed of a conductive film being transparent to the emitted light wavelength, and part of the conductive film is in contact with the nitride semiconductor.

In the nitride semiconductor light emitting device of the present invention, it is preferable that the first reflection film is formed by alternately stacking first nitride semiconductor films and second nitride semiconductor films having different compositions, and each of the first nitride semiconductor films and the second nitride semiconductor films has a film thickness of ¼ of an optical wavelength corresponding to an emitted light wavelength.

In this structure, the first reflection film constitutes a DBR mirror formed of the nitride semiconductor, and thus the first reflection film has a higher reflectivity. Therefore, it is possible to realize a nitride semiconductor surface emitting laser device having a lower oscillation threshold. Moreover, since the film thickness of the nitride semiconductor can be increased, the crystalline quality of the light-emission region is improved, so that the internal quantum efficiency increases.

In this case, it is preferable that the first nitride semiconductor film is made of GaN, and the second nitride semiconductor film is made of AlₓIn_{y}Ga_{1-x-y}N (where 0≦x≦1, 0≦y≦1, and x+y<1).

In this structure, it is possible to reduce the difference between the lattice constants of the first reflection film and the pn junction diode structure including a light-emission region, which improves the crystalline quality of the light-emission region, thereby increasing the internal quantum efficiency. Therefore, it is possible to realize a nitride semiconductor surface emitting laser device having a lower oscillation threshold.

If the nitride semiconductor light emitting device of the present invention includes the first reflection film formed of the nitride semiconductor, it is preferable that the nitride semiconductor light emitting device further includes a second reflection film over the first reflection film, wherein the second reflection film is formed by alternately stacking third dielectric films and fourth dielectric films having different compositions, and each of the third dielectric films and the fourth dielectric films has a film thickness of ¼ of the optical wavelength corresponding to the emitted light wavelength.

In this structure, the first reflection film formed of the nitride semiconductor and second the reflection film made of the dielectric substance form a DBR mirror and has a higher reflectivity, so that it is possible to realize a nitride semiconductor surface emitting laser device having a lower oscillation threshold. Moreover, the film thickness of the nitride semiconductor can be increased, and thus the sheet resistance can be reduced. Therefore, it is possible to realize a nitride semiconductor surface emitting laser device having a lower series resistance.

It is preferable that the nitride semiconductor light emitting device of the present invention further includes a current confinement layer in the pn junction diode structure under the first reflection film, the current confinement layer having an opening which opens in a direction vertical to a substrate surface.

In this structure, the current confinement layer restricts a path through which the injected current flows within the light exit region, and thus it is possible to realize a surface emitting laser device having a lower oscillation threshold.

In this case, it is preferable that the current confinement layer is covered with GaN.

In this structure, a high-quality nitride semiconductor layer having few crystal defects grows over the current confinement layer, which makes it possible to increase the carrier concentration. Therefore, it is possible to realize a nitride semiconductor surface emitting laser device having a lower oscillation threshold and a lower series resistance.

It is preferable that the nitride semiconductor light emitting device of the present invention further includes a third reflection film between the dielectric layered film and the pn junction diode structure, wherein the third reflection film is formed by alternately stacking third nitride semiconductor films and fourth nitride semiconductor films having different compositions, and each of the third nitride semiconductor films and the fourth nitride semiconductor films has a film thickness of ¼ of an optical wavelength corresponding to an emitted light wavelength.

In this structure, the third reflection film formed of the nitride semiconductor constitutes a DBR mirror and has a higher reflectivity, so that it is possible to realize a nitride semiconductor surface emitting laser device having a lower oscillation threshold.

Moreover, in the nitride semiconductor light emitting device of the present invention, it is preferable that the semiconductor thin film is transparent to an emitted light wavelength.

In this structure, the absorption of light by the semiconductor thin film can be reduced, and thus more light generated in the pn junction diode structure can be confined. Therefore, it is possible to realize a nitride semiconductor surface emitting laser device having a lower oscillation threshold.

In this case, it is preferable that the semiconductor thin film is formed of a mixed crystal of silicon carbide (SiC) and aluminum nitride (AlN).

In this structure, the mixed crystal of SiC and AlN has a band gap of greater than 3 eV, so that it is possible to realize a surface emitting laser device formed of the nitride semiconductor having a lower oscillation threshold in a wavelength range within which even blue light is not absorbed.

If the nitride semiconductor light emitting device of the present invention includes the first reflection film, it is preferable that the pn junction diode structure partially forms a resonator, and the resonator is in contact with a p-side electrode or an n-side electrode.

In this structure, it is possible to reduce the distance between the light-emission region included in the pn junction diode structure and the electrode, and thus the path through which a current flows can be shortened. Therefore, it is possible to realize a nitride semiconductor surface emitting laser device having a lower series resistance. Moreover, since heat generated in the light-emission region can be efficiently released via the electrode, the reliability can be improved.

A method for fabricating a nitride semiconductor light emitting device of the present invention includes the steps of: (a) alternately stacking a plurality of dielectric films having different compositions over a substrate to form a dielectric layered film; (b) bonding a semiconductor thin film formed of a single crystal to the dielectric layered film; and (c) forming a pn junction diode structure formed of a nitride semiconductor over the semiconductor thin film.

According to the method for fabricating the nitride semiconductor light emitting device of the present invention, the nitride semiconductor is formed over the dielectric layered film on the substrate, with the semiconductor thin film provided therebetween. In this case, the film thickness of the semiconductor thin film is reduced to such an extent that light penetrates through the semiconductor thin film, so that light absorption by the semiconductor thin film can be reduced. Moreover, since light emitted from the pn junction diode structure formed of the nitride semiconductor is reflected by the dielectric layered film, light extraction efficiency is improved. Therefore, it is possible to realize a higher-luminance nitride semiconductor light emitting device.

In the method for fabricating the nitride semiconductor light emitting device of the present invention, it is preferable that each of the dielectric films has a film thickness of ¼ of an optical wavelength corresponding to an emitted light wavelength.

According to this method, the dielectric layered film constitutes a DBR mirror, and thus the dielectric layered film has a higher reflectivity. Therefore, it is possible to realize a nitride semiconductor light emitting device having a lower oscillation threshold.

In the method for fabricating the nitride semiconductor light emitting device of the present invention, it is preferable that step (b) includes a first step of preparing a semiconductor substrate having a hydrogen injection region where ions of hydrogen are injected to a predetermined depth in a whole area of a principal surface of the semiconductor substrate; a second step of bonding the principal surface of the semiconductor substrate to the dielectric layered film; and a third step of heating the semiconductor substrate bonded to the dielectric layered film to peel off the semiconductor substrate at the hydrogen injection region.

According to this method, it is possible to certainly bond the semiconductor thin film having a predetermined film thickness to the dielectric layered film.

In the method for fabricating the nitride semiconductor light emitting device of the present invention, it is preferable that the semiconductor thin film is made of silicon (Si).

In the method for fabricating the nitride semiconductor light emitting device of the present invention, it is preferable that the semiconductor substrate is made of silicon (Si); and the first step includes subjecting the semiconductor substrate to a hydrocarbon gas such that a region of the semiconductor substrate for forming the semiconductor thin film is converted to silicon carbide (SiC).

According to this method, the lattice constant of SiC is relatively close to the lattice constant of GaN, and thus it is possible to obtain the pn junction structure formed of a nitride semiconductor having a better crystalline quality on a thin film having a principal surface whose plane direction is a (111) plane.

In the method for fabricating the nitride semiconductor light emitting device of the present invention, it is preferable that step (a) includes forming a glass-like film in a lower or upper portion of the dielectric layered film, and step (c) includes performing crystal growth of the nitride semiconductor at a temperature higher than a temperature for liquefaction of the glass-like film.

According to this method, it is possible to relieve stress generated between the substrate and the nitride semiconductor after the epitaxial growth. Therefore, it is possible to increase the film thickness of the nitride semiconductor without causing cracks in the nitride semiconductor, and thus it is possible to improve the crystalline quality of the nitride semiconductor. As a result, it is possible to obtain a higher-luminance nitride semiconductor light emitting device.

In this case, it is preferable that the glass-like film includes at least one of PSG (Phospho Silicate Glass) and BPSG (Boro Phospho Silicate Glass).

### BRIEF DESCRIPTION OF THE DRAWINGS

FIG. 1 is a cross-sectional view illustrating a structure of a nitride semiconductor light emitting device of Embodiment 1 of the present invention.

FIG. 2 is a graph showing the relationship between (i) the vertical reflectivity of a substrate including a semiconductor thin film and a multilayer DBR mirror and (ii) the film thickness of the semiconductor thin film of the nitride semiconductor light emitting device of Embodiment 1 of the present invention.

FIG. 3 is a graph showing the relationship between the emitted light wavelength and the vertical reflectivity as to various numbers of stacked layer pairs of SiO₂/TiO₂ constituting the multilayer DBR mirror of the nitride semiconductor light emitting device of Embodiment 1 of the present invention.

FIG. 4 is a graph showing the relationship between the incident angle of emitted light having a wavelength of 470 nm and the reflectivity of the nitride semiconductor light emitting device of Embodiment 1 of the present invention.

FIGS. 5A and 5B are cross-sectional views illustrating structures in respective steps of a method for fabricating the nitride semiconductor light emitting device of Embodiment 1 of the present invention in the order of fabrication.

FIGS. 6A and 6B are cross-sectional views illustrating structures in respective steps of the method for fabricating the nitride semiconductor light emitting device of Embodiment 1 of the present invention in the order of fabrication.

FIGS. 7A and 7B are cross-sectional views illustrating structures in respective steps of the method for fabricating the nitride semiconductor light emitting device of Embodiment 1 of the present invention in the order of fabrication.

FIG. 8 is a cross-sectional view illustrating a structure of a nitride semiconductor light emitting device of Variation 1 of Embodiment 1 of the present invention.

FIG. 9 is a cross-sectional view illustrating a structure of a nitride semiconductor light emitting device of Variation 2 of Embodiment 1 of the present invention.

FIG. 10A is a plan view illustrating a nitride semiconductor light emitting device of Embodiment 2 of the present invention. FIG. 10B is a cross-sectional view illustrating a structure taken along the line Xb-Xb of FIG. 10A.

FIG. 11 is a graph showing the relationship between (i) the numbers of cycles of GaN/AlN in a lower reflection film and of SiO₂/TiO₂ in a multilayer DBR mirror and (ii) the vertical reflectivity with respect to emitted light having a wavelength of 470 nm of the nitride semiconductor light emitting device of Embodiment 2 of the present invention.

FIG. 12 is a graph showing the relationship between (i) the number of cycles of GaN/AlN in the lower reflection film and the film thickness of a semiconductor thin film and (ii) the vertical reflectivity with respect to emitted light having a wavelength of 470 nm of the nitride semiconductor light emitting device of Embodiment 2 of the present invention.

[symbol] 13 is a graph showing the relationship between (i) the film thickness of a p-side transparent electrode and the number of cycles of SiO₂/TiO₂ in an upper reflection film 220 and (ii) the vertical reflectivity with respect to emitted light having a wavelength of 470 nm of the nitride semiconductor light emitting device of Embodiment 2 of the present invention.

FIG. 14 is a cross-sectional view illustrating a structure of a nitride semiconductor light emitting device of Variation 1 of Embodiment 2 of the present invention.

FIG. 15 is a cross-sectional view illustrating a structure of a nitride semiconductor light emitting device of Variation 2 of Embodiment 2 of the present invention.

FIG. 16 is a graph showing the relationship between (i) the number of cycles of SiO₂/TiO₂ in a first upper reflection film and the number of cycles of GaN/AlGaN in a second upper reflection film and (ii) the vertical reflectivity with respect to emitted light having a wavelength of 470 nm of the nitride semiconductor light emitting device of Variation 2 of Embodiment 2 of the present invention.

### DESCRIPTION OF THE PREFERRED EMBODIMENTS

### Embodiment 1

A nitride semiconductor light emitting device of Embodiment 1 of the present invention and a method for fabricating the same are described with reference to the drawings.

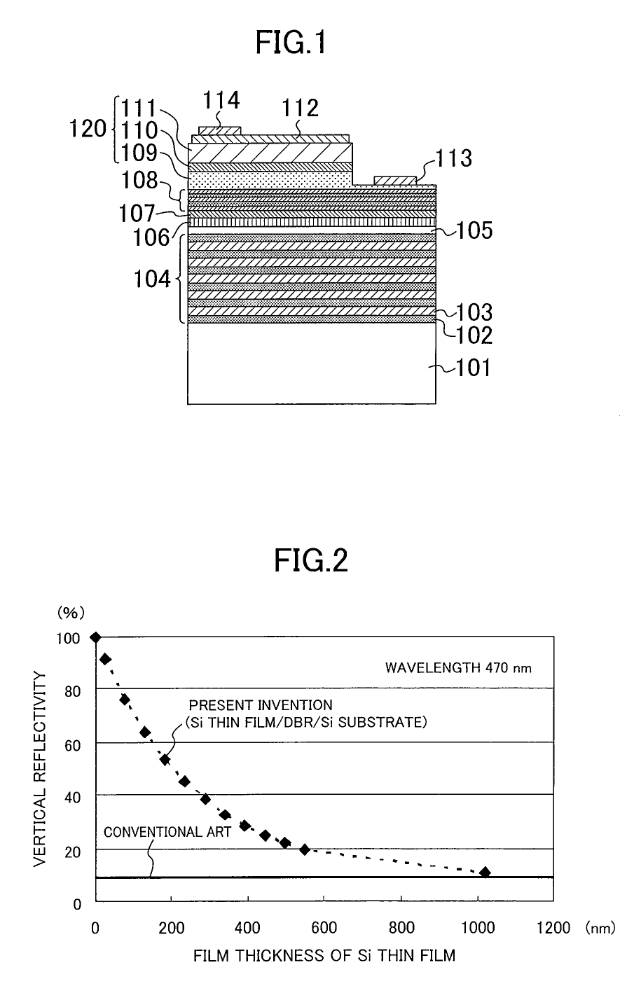

FIG. 1 shows a cross-sectional structure of the nitride semiconductor light emitting device, which serves as a light emitting diode, of Embodiment 1 of the present invention. As shown in FIG. 1, over a substrate 101, a multilayer DBR mirror 104 and a semiconductor thin film 105 are sequentially formed. The substrate 101 is made of, for example, silicon (Si) having a principal surface whose plane direction is a (111) plane. The multilayer DBR mirror 104 includes at least a pair of first dielectric films 102 made of silicon oxide (SiO₂) and second dielectric films 103 made of titanium oxide (TiO₂) which are alternately stacked. The semiconductor thin film 105 is made of a Si single crystal having a principal surface (upper surface) whose plane direction is a (111) plane.

Over the semiconductor thin film 105, an initial layer 106 made of aluminum nitride (AlN); an interlayer 107 made of aluminum gallium nitride (AlGaN); a cycle structure 108 formed of a layered film of AlN and GaN; an n-type cladding layer 109 made of n-type GaN; a multi-quantum-well (MQW) active layer 110 formed of a layered film of indium gallium nitride (InGaN) and GaN; and a p-type cladding layer 111 made of p-type AlGaN are sequentially epitaxially grown by metal organic chemical vapor deposition (MOCVD) or the like. Therefore, in Embodiment 1, the substrate 101, the multilayer DBR mirror 104, and the semiconductor thin film 105 practically constitute a substrate for crystal growth.

In Embodiment 1, the n-type cladding layer 109, the MQW active layer 110, and the p-type cladding layer 111 constitute a pn junction diode structure 120. It is to be noted that the configuration in this embodiment includes the undoped MQW active layer 110 provided between the n-type cladding layer 109 and p-type cladding layer 111, but this configuration is referred to as a pn junction in a broad sense.

On the p-type cladding layer 111, a transparent electrode 112 made of indium tin oxide (ITO) is provided.

Part of the n-type cladding layer 109 is exposed by, for example, etching, and an n-side electrode 113 is formed in the exposed part. The n-side electrode 113 is made of, for example, titanium (Ti)/aluminum (Al)/nickel (Ni)/gold (Au) and has ohmic characteristics. Moreover, on the transparent electrode 112, a p-side pad electrode 114 made of Ti/Al/Ni/Au is selectively provided.

Each of the first dielectric films 102 of SiO₂ and the second dielectric films 103 of TiO₂ is formed to have a film thickness of λ/(4n) (where n is the refractive index of SiO₂ or TiO₂) with respect to the emitted light wavelength of λ and designed such that a high reflectivity with respect to the emitted light wavelength can be obtained. Specifically, with respect to the emitted light wavelength of 470 nm, the first dielectric film 102 has a film thickness of 81 nm and the second dielectric film 103 has a film thickness of 45 nm. A top surface of the multilayer DBR mirror 104 is terminated with the first dielectric film 102. In contact with the first dielectric film 102, the semiconductor thin film 105 is provided. The semiconductor thin film 105 is made of, for example, silicon whose principal surface is a (111) plane and which has a film thickness of 25 nm.

The interlayer 107 made of AlGaN and the cycle structure 108 formed of the layered film of AlN/GaN which are formed between the semiconductor thin film 105 and the pn junction diode structure 120 are provided for the purpose of relieving stress in epitaxial growth of the pn junction diode structure 120 over the semiconductor thin film 105. The interlayer 107 is made of, for example, Al_{0.27}Ga_{0.73}N having a thickness of 20 nm. The cycle structure 108 is formed by stacking 20 pairs of GaN having a thickness of 20 nm and AlN having a thickness of 5 nm.

As described above, the light emitting diode of Embodiment 1 includes the multilayer DBR mirror 104 formed of a layered film of SiO₂/TiO₂ having a high reflectivity with respect to the emitted light wavelength, the multilayer DBR mirror 104 being provided between the pn junction diode structure 120 formed of a nitride semiconductor and the substrate 101 made of Si. Therefore, the light emitting diode of Embodiment 1 has a feature that the absorption of emitted light by the Si substrate, which was a problem in the conventional nitride semiconductor light emitting device using a Si substrate, is suppressed, and the light power can be improved by a high-reflectivity mirror formed of the multilayer DBR mirror 104.

FIG. 2 shows the relationship between the film thickness of the semiconductor thin film 105 of the light emitting diode of Embodiment 1 of the present invention and the reflectivity (vertical reflectivity) with respect to emitted light coming from the pn junction diode structure 120 and having a wavelength of 470 nm. Here, only the reflectivity in the case of the semiconductor thin film 105 having a film thickness of m/4 (where m is an odd number) of the optical wavelength where the reflectivity has the maximum value is shown. As can be seen from FIG. 2, in the conventional structure in which a nitride semiconductor layer is directly formed on the Si substrate without providing the multilayer DBR mirror 104, the Si substrate has a reflectivity of only about 10%. Compared to this, in the light emitting diode of the present invention, as the film thickness of the semiconductor thin film 105 formed on the multilayer DBR mirror 104 is reduced, the reflectivity approaching almost 100% can be ensured. On the other hand if the film thickness of the semiconductor thin film 105 made of Si increases, light absorption by the semiconductor thin film becomes remarkable, and thus the reflectivity approaches the reflectivity in the case of the conventional Si substrate. Therefore, compared to the conventional structure, the semiconductor thin film 105 desirably has a film thickness of 1 μm or less where the reflectivity is improved by the multilayer DBR mirror 104, and more desirably has a film thickness of 600 nm or less. It is to be noted that the semiconductor thin film 105 is required to have a thickness allowing epitaxial growth of the nitride semiconductor inclusive of the pn junction diode structure 120. That is, it is desirable that a surface of the semiconductor thin film 105 is smooth, and therefore, the semiconductor thin film 105 preferably has a film thickness of 10 nm or greater such that the surface of the semiconductor thin film 105 is even and flat.

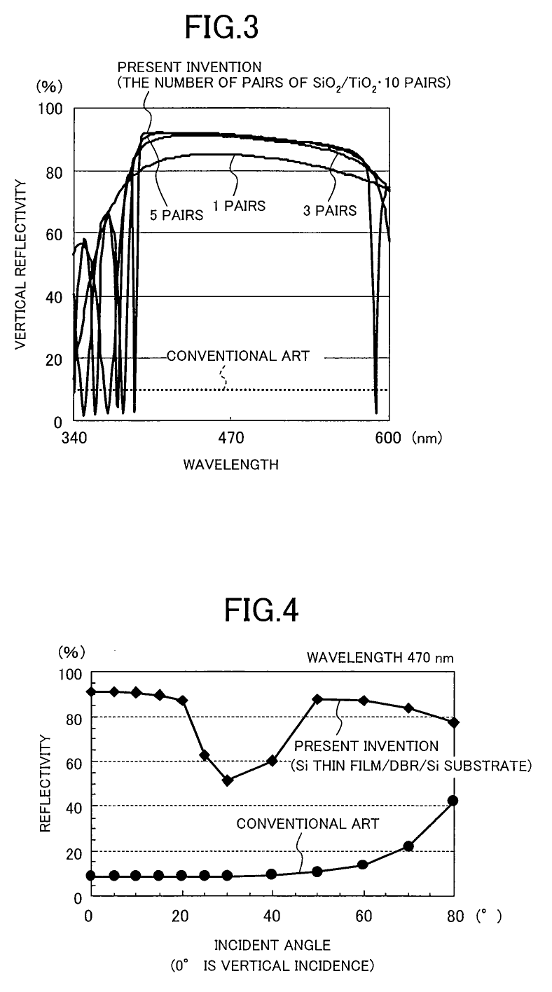

FIG. 3 shows the relationship between the wavelength of emitted light coming from the pn junction diode structure 120 and the reflectivity (vertical reflectivity) as to various numbers of stacked layer pairs of SiO₂/TiO₂ constituting the multilayer DBR mirror 104 of the light emitting diode of Embodiment 1 of the present invention. As can be seen from FIG. 3, the reflectivity is improved by providing the multilayer DBR mirror 104 including at least a pair of SiO₂/TiO₂. Further, if the number of stacked layer pairs is 3 or more, a reflectivity of higher than or equal to 90%, which shows a high reflectivity characteristic, can be ensured especially in a wavelength range within ±50 nm from the wavelength of 470 nm.

In this way, also in the light emitting diode having emitted light wavelength distribution, the light power can be improved.

FIG. 4 shows the relationship between the reflectivity and the incident angle of emitted light coming from the pn junction diode structure 120 of the light emitting diode of Embodiment 1 of the present invention and having a wavelength of 470 nm. As can be seen from FIG. 4, light generated by the pn junction diode structure 120 is emitted in all directions, but according to the light emitting diode of Embodiment 1, a high reflectivity can be ensured in all incident angels compared to the conventional structure including only the Si substrate. The result shows that taking consideration of effects of a solid angle, the reflectivity of the semiconductor thin film 105, the multilayer DBR mirror 104, and the substrate 101 is 4 times greater than that of the conventional configuration including only the Si substrate.

A method for fabricating the light emitting diode structured as mentioned above will be described below with reference to the drawings.

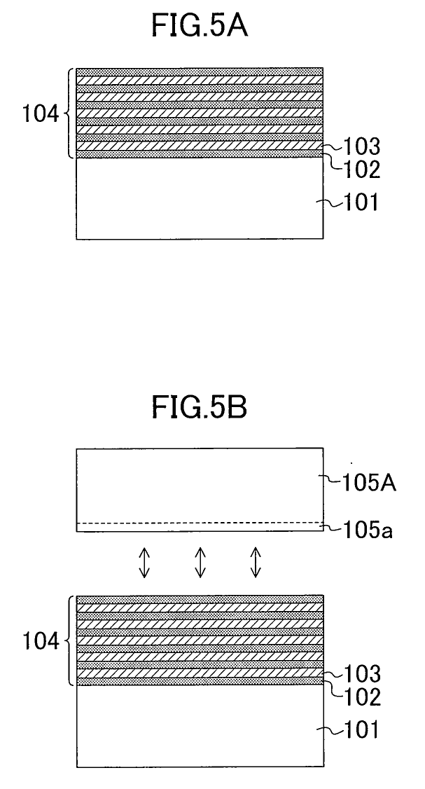

FIGS. 5A and 5B through FIGS. 7A and 7B show cross sectional structures in respective steps of the method for fabricating a light emitting diode formed of a nitride semiconductor of Embodiment 1 of the present invention in the order of fabrication.

As illustrated with FIG. 5A, over a principal surface of a substrate 101, for example five pairs of first dielectric films 102 and second dielectric films 103 are first formed by high frequency sputtering or the like to form a multilayer DBR mirror 104. The substrate 101 is made of Si having a principal surface whose plane direction is a (111) plane. The first dielectric film 102 is to be a low refractive index layer and made of SiO. The second dielectric film 103 is to be a high refractive index layer and made of TiO₂. In this embodiment, as the low refractive index layer, magnesium fluoride (MgF₂) or the like may be used instead of SiO₂, and as the high refractive index layer, tantalum oxide (Ta₂O₅), zirconium oxide (ZrO₂), silicon nitride (Si₃N₄), or the like may be used instead of TiO₂. If the multilayer DBR mirror 104 includes a combination of a low refractive index layer and a high refractive index layer which have refractive indices greatly different from each other, a high reflectivity can be obtained with a small number of stacked layer pairs. Therefore, the number of stacked layer pairs in the multilayer DBR mirror 104 may be 3.

Then, as illustrated with FIG. 5B, on an upper surface of the formed multilayer DBR mirror 104, a Si thin film formation substrate 105A is adhered. The Si thin film formation substrate 105A is made of single crystal Si having a principal surface whose plane direction is a (111) plane. For the adhesion, a so-called direct bonding method may be used in which surfaces subjected to a hydrophilic treatment are brought into direct contact with each other and heated for adhesion. It is to be noted that the Si thin film formation substrate 105A has a principal surface in whole area of which a hydrogen ion implantation region 105a is previously formed by implanting hydrogen ions to a depth of, for example, 25 nm.

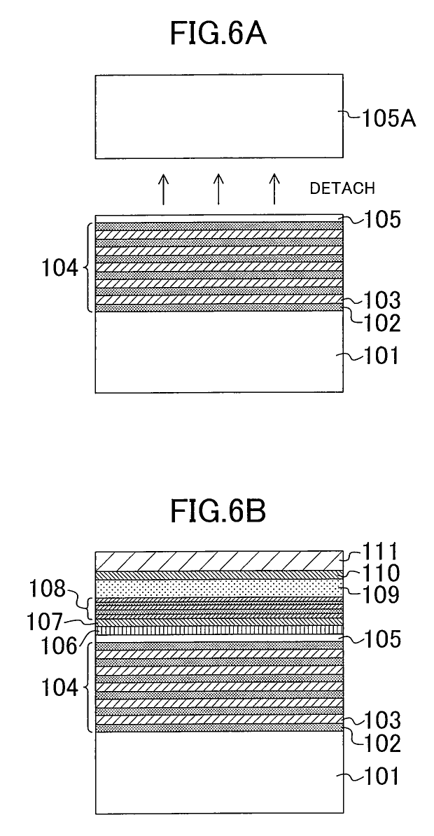

Then, as illustrated with FIG. 6A, the Si thin film formation substrate 105A is bonded to the substrate 101 through the multilayer DBR mirror 104. After that, so-called Smart-Cut is performed in which a thermal treatment is performed to selectively detach only the hydrogen ion implantation region 105a, thereby leaving a semiconductor thin film 105 on the multilayer DBR mirror 104. The semiconductor thin film 105 is formed of the hydrogen ion implantation region 105a of the Si thin film formation substrate 105A. The Smart-Cut permits the semiconductor thin film 105 made of Si having a principal surface whose plane direction is a (111) plane is to be thin to such the extent that emitted light from the pn junction diode structure sufficiently penetrates through the semiconductor thin film 105. Therefore, the absorption of the emitted light is sufficiently suppressed, and thus the power of the light emitting diode can be increased.

Here, the semiconductor thin film 105 may be carbonized by a hydrocarbon gas such as propane (C₃H₈) to convert single crystal silicon (Si) to single crystal silicon carbide (SiC). In this case, since the silicon carbide (SiC) has a lattice constant relatively similar to a lattice constant of GaN, it is possible to form a nitride semiconductor layer having a better crystalline quality on the semiconductor thin film 105. Moreover, since the silicon carbide (SiC) does not absorb blue light for example, the power can be increased. Alternatively, the semiconductor thin film 105 may be made of gallium nitride (GaN) instead of Si and SiC. In this structure, it is possible to form a nitride semiconductor having a much better crystalline quality on the multilayer DBR mirror 104.

Then, as illustrated with FIG. 6B, MOCVD is performed to sequentially form an initial layer 106 made of AlN, an interlayer 107 made of AlGaN, a cycle structure 108 formed of a layered film of AlN/GaN, an n-type cladding layer 109 made of n-type GaN, a MQW active layer 110 formed of a layered film of InGaN/GaN, and a p-type cladding layer 111 made of a p-type AlGaN on the semiconductor thin film 105. Here, a monosilane (SiH₄) gas is added to the n-type cladding layer 109 to dope the n-type cladding layer 109 with Si which serves as an n-type impurity. Moreover, bis-cyclopentadienyl magnesium (Cp₂Mg) is added to the p-type cladding layer 111 to dope the p-type cladding layer 111 with Mg which serves as a p-type impurity. Moreover, the MQW active layer 110 has a composition structured such that current injection causes emission of light of 470 nm.

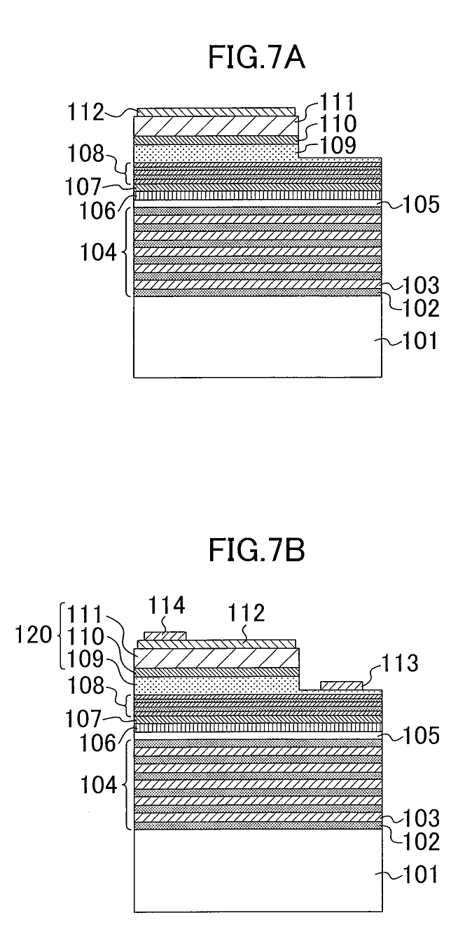

Then, as illustrated with FIG. 7A, sputtering is performed to from a transparent electrode 112 made of ITO having a thickness of 100 nm on the grown p-type cladding layer 111. The formed transparent electrode 112 has a transmittance of higher than or equal to 90% to emitted light generated by the MQW active layer 110 and having a wavelength of about 470 nm, and the light absorption by the transparent electrode 112 is adequately suppressed. It is to be noted that instead of the transparent electrode 112 made of ITO, a p-side electrode made of nickel (Ni)/gold (Au) may be formed directly on the p-type cladding layer 111. Subsequently, dry etching using inductively coupled plasma (ICP) or the like adopting an etching gas such as a chlorine (Cl₂) gas is performed to etch the transparent electrode 112, the p-type cladding layer 111, the MQW active layer 110, and the n-type cladding layer 109 to expose the n-type cladding layer 109, with part of the n-type cladding layer 109 being left.

Then, as illustrated with FIG. 7B, electron-beam evaporation is performed to form an n-side electrode 113 made of Ti/Al/Ni/Au having a thickness of 300 nm on the exposed n-type cladding layer 109. Subsequently, electron-beam evaporation is performed to form a p-side pad electrode 114 made of Ti/Al/Ni/Au on the transparent electrode 112 in the same manner as the n-side electrode 113. It is to be noted that the formation of the n-side electrode 113 and the p-side pad electrode 114 may be performed in any order. The n-side electrode 113 and the p-side pad electrode 114 can be formed in one step.

As mentioned above, according to Embodiment 1, by using a high reflectivity obtained by the multilayer DBR mirror 104 having a high reflectivity with respect to the emitted light wavelength, it is possible to form a nitride semiconductor light emitting device having a high light power, i.e. a light emitting diode formed of a nitride semiconductor.

As a substrate for crystal growth, the substrate 101 which has a greater diameter and is made of Si being available at lower price compared to sapphire or silicon carbide and the Si thin film formation substrate 105A are used. Therefore, a nitride semiconductor light emitting device having a high power can be realized at a low cost.

### Variation 1 of Embodiment 1

Variation 1 of Embodiment 1 of the present invention will be described below with reference to the drawings.

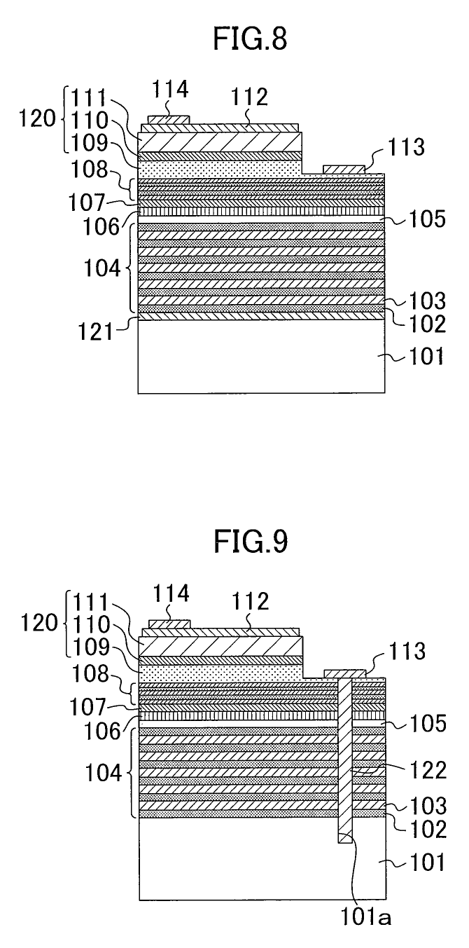

FIG. 8 shows a cross-sectional structure of a light emitting diode of Variation 1 of Embodiment 1 of the present invention. In FIG. 8, the same components as those of FIG. 1 are indicated by the same numerals and descriptions thereof are omitted.

As shown in FIG. 8, the light emitting diode of Variation 1 includes a phospho silicate glass (PSG) film 121 having a film thickness of, for example, 500 nm between the substrate 101 and the multilayer DBR mirror 104.

Now, silicon (Si) and gallium nitride (GaN) are greatly different in thermal expansion coefficient, and a thermal expansion coefficient of Si is smaller than a thermal expansion coefficient of GaN. Therefore, tensile stress from Si is exerted on GaN when a temperature falls after the crystal growth performed by MOCVD, thereby causing cracks. Therefore, the maximum film thickness to which the nitride semiconductor such as GaN is allowed to grow is limited.

To solve the problem, according to the present variation, the PSG film 121 is provided between the substrate 101 and the multilayer DBR mirror 104, so that it is possible to relieve stress generated in the nitride semiconductor due to a temperature change after the epitaxial growth. As a result, it becomes possible to increase the film thickness of the nitride semiconductor without causing cracks. Therefore, the crystalline quality of the nitride semiconductor in the nitride semiconductor light emitting device is improved to realize an increase of luminance.

Specifically, the PSG film 121 is lower in softening point, which is a temperature at which liquefaction starts, than silicon oxide (SiO₂). Therefore, the softening point of the PSG film 121 can be set to a temperature equal to or lower than an epitaxial growth temperature of GaN. Therefore, when epitaxial growth of the nitride semiconductor layer is performed, the PSG film 121 can be grown in a liquefaction (softened) state. Therefore, the stress generated in the nitride semiconductor due to the temperature change after the growth can be relieved.

It is to be noted that the PSG film 121 may be provided between the multilayer DBR mirror 104 and the semiconductor thin film 105. However, to reduce occurrences of cracks in the nitride semiconductor inclusive of the pn junction diode structure 120, it is preferable that the PSG film 121 is formed in contact with the semiconductor thin film 105.

As in Embodiment 1, the multilayer DBR mirror 104 is structured such that each of the SiO₂/TiO₂ layers is formed to have a film thickness corresponding to ¼ of the optical wavelength, and for example, 5 or 3 pairs of the SiO₂/TiO₂ layers realize a reflectivity of higher than or equal to 90%.

In Variation 1, as long as the softening point can be lowered, a boro phospho silicate glass (BPSG) film may be used instead of the PSG film 121. Alternatively, PSG and BPSG may be used simultaneously. The softening point of the BPSG film is about 800° C. which is much lower than the softening point of the PSG film, which is about 1000° C. Therefore, the stress generated in the nitride semiconductor after the epitaxial growth of the nitride semiconductor is more reduced than in the case where the PSG film is used. Therefore, a thicker nitride semiconductor can be grown without causing cracks, and thus a high-luminance nitride semiconductor light emitting device excellent in crystalline quality can be realized.

### Variation 2 of Embodiment 1

Variation 2 of Embodiment 1 of the present invention will be described below with reference to the drawings.

FIG. 9 shows a cross sectional structure of a light emitting diode of Variation 2 of Embodiment 1 of the present invention. In FIG. 9, the same components as those of FIG. 1 are indicated by the same numerals and descriptions thereof are omitted.

As shown in FIG. 9, the light emitting diode of Variation 2 includes a conductive member 122 formed in a through-hole 101a, wherein the conductive member 122 electrically connects the n-side electrode 113 with the substrate 101 and is made of gold (Au). The through-hole 101a is formed through the n-type cladding layer 109, the cycle structure 108, the interlayer 107, the initial layer 106, the semiconductor thin film 105, and the multilayer DBR mirror 104 to an upper portion of the substrate 101. The through-hole 101a can be formed by performing dry etching using an etching gas whose main component is, for example, chlorine on the nitride semiconductor and the substrate 101 and performing dry etching using an etching gas whose main component is, for example, fluorocarbon on the multilayer DBR mirror 104. Moreover, the conductive member 122 can be formed by performing gold plating to embed gold in the formed through-hole 101a.

In the present variation, in an operation state of the light emitting diode, heat generated by the nitride semiconductor inclusive of the pn junction diode structure 120 is conducted via conductive member 122 to the substrate 101 and released. This suppresses a temperature rise of the nitride semiconductor in the operation state, and thus degradation of internal quantum efficiency caused by the temperature rise is suppressed. Therefore, a higher-luminance nitride semiconductor light emitting device can be realized.

If the substrate 101 is formed to have conductivity and an n-side electrode (back surface electrode) is further provided on a surface of the substrate 101 opposite to the multilayer DBR mirror 104, wiring to the n-side electrode 113 provided on the n-type cladding layer 109 is no longer necessary. Therefore, the packing area of the nitride semiconductor light emitting device can be reduced.

As in Variation 1, a PSG film or a BPSG film may be provided between the substrate 101 and the multilayer DBR mirror 104.

### Embodiment 2

Embodiment 2 of the present invention will be described below with reference to the drawings.

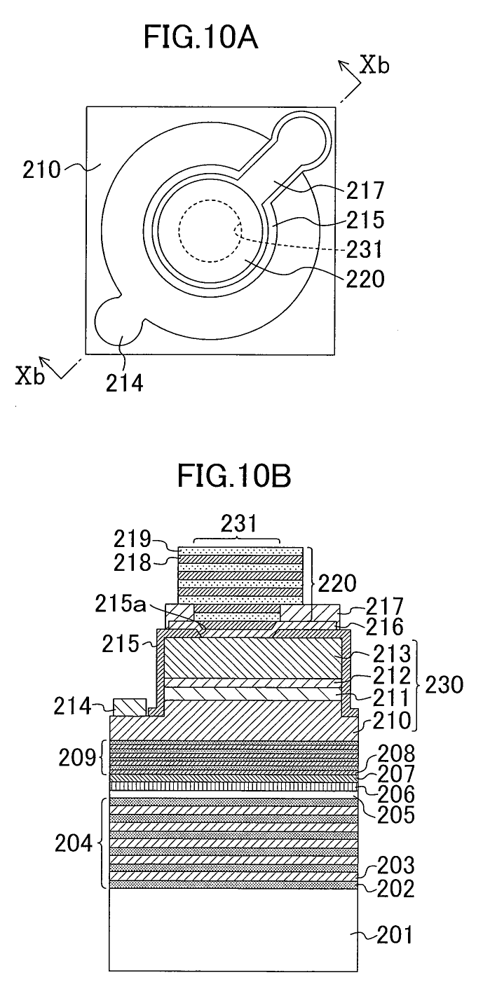

FIGS. 10A and 10B show a nitride semiconductor light emitting device, which serves as a surface emitting laser device, of Embodiment 2 of the present invention, wherein FIG. 10A shows a plan structure and FIG. 10B shows a cross sectional structure taken along the line Xb-Xb of FIG. 10A.

As shown in FIG. 10B, on a substrate 201 made of, for example, Si having a principal surface whose plane direction is a (111) plane, a multilayer DBR mirror 204, a PSG film 205, and a semiconductor thin film 206 are sequentially formed. The multilayer DBR mirror 204 includes at least a pair of first dielectric films 202 made of SiO₂ and second dielectric films 203 made of TiO₂ which are alternately stacked. The semiconductor thin film 206 is formed of a single crystal of silicon carbide (SiC) having a principal surface whose plane direction is a (111) plane.

On the semiconductor thin film 206, a lower reflection film 209, an n-type cladding layer 210 made of n-type GaN, a multi-quantum-well (MQW) active layer 211 formed of a layered film of InGaN and GaN, an electron overflow suppression layer 212 made of p-type AlGaN, and a p-type cladding layer 213 made of p-type AlGaN are formed sequentially epitaxially grown by MOCVD for example. The lower reflection film 209 is formed of a layered film (semiconductor DBR mirror) including at least a pair of first nitride semiconductor films 207 made of n-type GaN and second nitride semiconductor films 208 made of n-type AlN which are alternately stacked. Therefore, in Embodiment 2, the substrate 201, the multilayer DBR mirror 204, the PSG film 205, and the semiconductor thin film 206 practically constitute a substrate for crystal growth.

Moreover, in Embodiment 2, the n-type cladding layer 210, the MQW active layer 211, the electron overflow suppression layer 212, and the p-type cladding layer 213 constitute a pn junction diode structure 230. It is to be noted that the configuration in this embodiment includes the undoped MQW active layer 211 between the n-type cladding layer 210 and the p-type cladding layer 213, but this configuration is referred to as a pn junction in a broad sense.

As shown in FIGS. 10A and 10B, etching is performed from an upper portion of the n-type cladding layer 210 to the p-type cladding layer 213 to form a mesa shape. An n-side electrode 214 made of, for example, Ti/Al/Ni/Au is provided in the peripheral region of the mesa-shaped portion on the n-type cladding layer 210 exposed by the etching.

On the p-type cladding layer 213, a current confinement layer 215 made of SiO₂ and having an opening 215a is provided to cover an upper surface and side surface of the mesa-shaped portion.

On the current confinement layer 215, a p-side transparent electrode 216 made of ITO is provided. The p-side transparent electrode 216 is in contact with the p-type cladding layer 213 via the opening 215a. In the peripheral region of the p-side transparent electrode 216 excepting the opening 215a of the current confinement layer 215, a p-side pad electrode 217 made of, for example, Ti/Al/Ni/Au is provided.

Moreover, on the p-side transparent electrode 216, an upper reflection film 220 is formed. The upper reflection film 220 is in contact with the p-side pad electrode 217 at the peripheral portion thereof. The upper reflection film 220 is formed of a layered film (dielectric DBR mirror) including at least a pair of third dielectric films 218 made of SiO₂ and fourth dielectric films 219 made of TiO₂ which are alternately stacked.

As described above, the nitride semiconductor light emitting device of Embodiment 2 is the surface emitting laser device formed of a nitride semiconductor in which the pn junction diode structure 230 is provided between (i) the multilayer DBR mirror 204 and the lower reflection film 209 formed of the semiconductor DBR mirror and (ii) the upper reflection film 220 formed of a dielectric DBR mirror. It is to be noted that the numeral 213 shown in FIGS. 10A and 10B indicates an exit region of a laser beam.

Each of the first dielectric films 202 made of SiO₂ and the second dielectric films 203 made of TiO₂ constituting the multilayer DBR mirror 204 is formed to have a film thickness of λ/(4n) (where n is the refractive index of SiO₂ or TiO₂) with respect to the emitted light wavelength of λ and designed such that a high reflectivity with respect to the emitted light wavelength can be obtained. Specifically, with respect to the emitted light wavelength of 470 nm, the first dielectric film 102 has a film thickness of 81 nm and the second dielectric film 103 has a film thickness of 45 nm. The same configuration applies to the third dielectric film 218 made of SiO₂ and the fourth dielectric film 219 made of TiO₂ constituting the upper reflection film 220, which serves as a dielectric DBR mirror.

Moreover, each of the first nitride semiconductor films 207 made of n-type GaN and the second nitride semiconductor films 208 made of n-type AlN constituting the lower reflection film 209, which serves as a semiconductor DBR mirror, is formed to have a film thickness of λ/(4n) (where n is the refractive index of GaN or AlN) with the emitted light wavelength of λ and designed such that a high reflectivity with respect to the emitted light wavelength can be obtained. Specifically, with respect to the emitted light wavelength of 470 nm, the first nitride semiconductor film 207 has a film thickness of 47.8 nm and the second nitride semiconductor film 208 has a film thickness of 58 nm.

A total film thickness of the n-type cladding layer 210, the MQW active layer 211, the electron overflow suppression layer 212, and the p-type cladding layer 213 constituting the pn junction diode structure 230 is m₁·λ (where m₁ is a natural number) with respect to the emitted light wavelength of λ and designed such that a resonator is formed. Moreover, the film thickness from the n-type cladding layer 210 to a center part of the MQW active layer 211 is m₂·λ/2 (where m₂ is a natural number) and designed such that a high gain with respect to the emitted light wavelength can be obtained. Specifically, the n-type cladding layer 210 has a thickness of 81.1 nm, the MQW active layer 211 has a thickness of 29 nm, the electron overflow suppression layer 212 has a thickness of 10 nm, and the p-type cladding layer 213 has a thickness of 71.1 nm.

According to this structure, in the surface emitting laser device of Embodiment 2, it is possible to restrict a current to flow only directly under the exit region 231.

It is to be noted that instead of providing the current confinement layer 215 on the p-type cladding layer 213 to selectively cover the p-type cladding layer 213, the p-side transparent electrode 216 may be formed on the entire surface of the p-type cladding layer 213 under the condition that only part of the p-type cladding layer 213 corresponding to the light exit region 231 is selectively formed as a p-type semiconductor.

As described above, the surface emitting laser device formed of the nitride semiconductor of Embodiment 2 realizes a high reflectivity with respect to the emitted light wavelength by the multilayer DBR mirror 204, the PSG film 205, the semiconductor thin film 206, and the lower reflection film 209 formed of the semiconductor DBR mirror. According to the surface emitting laser device, it is possible to suppress the absorption of emitted light by a Si substrate, which was a problem of the conventional nitride semiconductor light emitting device using a Si substrate. Further, the surface emitting laser device has such a feature that a laser oscillation can be realized because a high light-confining effect can be obtained between the lower reflection film 209 and the upper reflection film 220 formed of a dielectric DBR mirror on the pn junction diode structure 230.

Generally, to realize the laser oscillation, a surface emitting laser device requires a pair of reflection films which face each other and have a high reflectivity. Specifically, it is desirable for the surface emitting laser device formed of the nitride semiconductor of Embodiment 2 that the lower reflection film 209 and the multilayer DBR mirror 204 have a reflectivity of about 99.8% and the upper reflection film 220 which is to serve as a light exit surface has a reflectivity of about 99%.

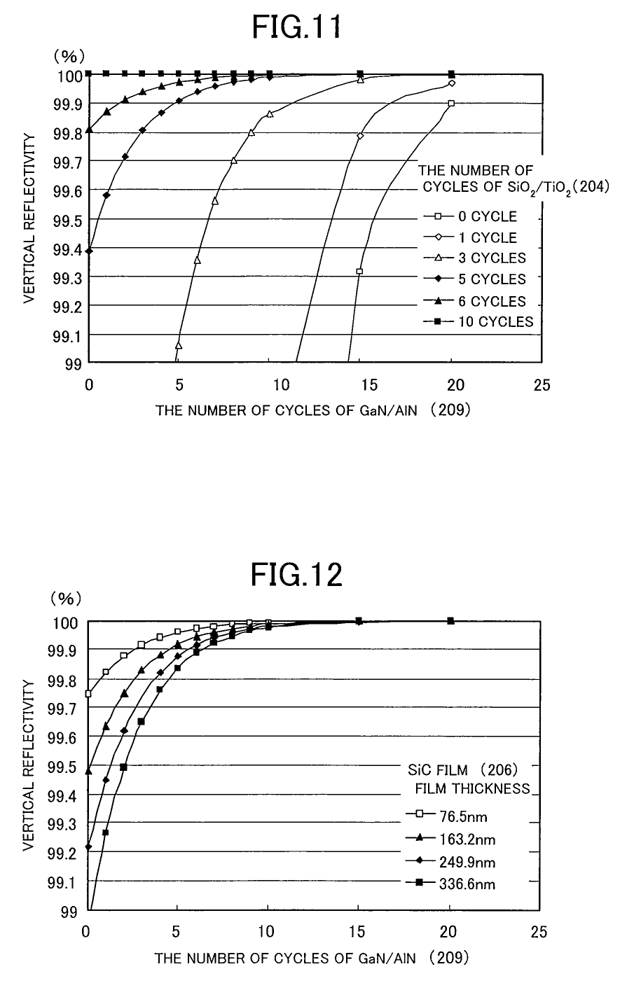

FIG. 11 shows the relationship between (i) the numbers of cycles of n-type GaN/n-type AlN constituting the lower reflection film 209 and of SiO₂/TiO₂ constituting the multilayer DBR mirror 204 and (ii) the vertical reflectivity with respect to emitted light coming from the pn junction diode structure 230 of the surface emitting laser device of Embodiment 2 of the present invention and having a wavelength of 470 nm.

The refractive indices of aluminum nitride (AlN) and gallium nitride (GaN) are respectively 2.03 and 2.46, and the difference between the two refractive indices is small. Therefore, in the case where the multilayer DBR mirror 204 is not provided (0 cycle), it is necessary that the lower reflection film 209 includes about 20 cycles of n-type GaN/n-type AlN in order to obtain a reflectivity of about 99.8%, although not shown in the drawing. However, if the film thickness of the nitride semiconductor is excessively increased, the difference between the lattice constants and the difference between the thermal expansion coefficients of the substrate for crystal growth and the lower reflection film cause stress, which may lead to occurrences of cracks in the nitride semiconductor.

To solve the problem, in Embodiment 2, as can be seen from FIG. 11, the multilayer DBR mirror 204 provided under the lower reflection film 209 is designed to have 3 or more cycles of SiO₂/TiO₂, so that the reflectivity of higher than or equal to 99.8% can be certainly realized by the lower reflection film 209 having 10 or less cycles of n-type GaN/n-type AlN. Moreover, to realize the reflectivity of higher than or equal to 99.8% regardless of the number of cycles of n-type GaN/n-type AlN in the lower reflection film 209, it is desirable that the number of cycles of SiO₂/TiO₂ in the multilayer DBR mirror 204 is set to greater than or equal to 6.

The surface emitting laser device of Embodiment 2 includes the PSG film 205 and the semiconductor thin film 206 made of SiC between the multilayer DBR mirror 204 and the lower reflection film 209. Here, it is desirable that a film thickness d_{PSG} of the PSG film 205 and a film thickness d_{SiC} of the semiconductor thin film 206 are expressed by

(d_{PSG}×n_{PSG}/λ)+(d_{SiC}×n_{SiC}/λ)=m₃/4

(where n_{PSG} and n_{SiC} are refractive indices respectively of the PSG film and the SiC film, λ is the emitted light wavelength, and m₃ is an odd number).

This allows the reflectivity of a lower reflection portion to be more increased, the lower reflection portion being formed of the lower reflection film 209 and the multilayer DBR mirror 204 inclusive of the PSG film 205 and the semiconductor thin film 206. Moreover, a SiC crystal structure which can be obtained by carbonizing a Si thin film formation substrate is a cubic crystal (3C-SiC) and has a band gap of 2.2 eV which is smaller than the emitted light wavelength (specifically, if the emitted light wavelength is 470 nm, the energy of light of the emitted light wavelength is 2.64 eV) in the blue range. Therefore, in order to reduce the absorption of light by the semiconductor thin film 206 made of SiC, it is desirable that the semiconductor thin film 206 has a small film thickness. Compared to this, in order to reduce light entering the semiconductor thin film 206, it is desirable that the lower reflection film 209 has a high reflectivity.

FIG. 12 shows the relationship between (i) the number of cycles of n-type GaN/n-type AlN constituting the lower reflection film 209 and the film thickness of the semiconductor thin film 206 and (ii) the vertical reflectivity with respect to emitted light coming from the pn junction diode structure 230 of the surface emitting laser device of Embodiment 2 of the present invention and having a wavelength of 470 nm. Here, the number of cycles of SiO₂/TiO₂ in the multilayer DBR mirror 204 is 10 and the PSG film 206 has a film thickness of 100 nm. As can be seen from FIG. 12, in the case where the lower reflection film 209 is not provided (0 cycle), the reflectivity lowers as the film thickness of the semiconductor thin film 206 made of SiC increases. Compared to this, increasing the number of cycles of n-type GaN/n-type AlN in the lower reflection film 209 makes it possible to obtain a reflectivity of higher than or equal to 99.8% with any film thickness of the semiconductor thin film 206. Therefore, to realize a high reflectivity regardless of the film thickness of the semiconductor thin film 206, it is desirable that the lower reflection film 209 is formed to have 5 or more cycles of n-type GaN/n-type AlN.

Moreover, to realize a high reflectivity even if the lower reflection film 209 has a small number of cycles of n-type GaN/n-type AlN, it is desirable that the film thickness of the semiconductor thin film 206 is set to be smaller than or equal to 350 nm.

It is to be noted that the semiconductor thin film 206 may be a mixed crystal of SiC and AlN instead of single crystal SiC. SiCAlN has a band gap of 3.2 eV, and this value is greater than the energy of light corresponding to the emitted light wavelength in the blue range, and thus blue light is not absorbed. Therefore, if the semiconductor thin film 206 is formed of the mixed crystal of SiC and AlN, it is possible to form the lower reflection portion having a high reflectivity.

FIG. 13 shows the relationship between (i) the film thickness of the p-side transparent electrode 216 made of ITO and the number of cycles of SiO₂/TiO₂ constituting the upper reflection film 220 and (ii) the vertical reflectivity with respect to emitted light coming from the pn junction diode structure 230 of the surface emitting laser device of Embodiment 2 of the present invention and having a wavelength of 470 nm. As can be seen from FIG. 13, in the case where the p-side transparent electrode 216 has a film thickness of 57.7 nm, a reflectivity of about 99% can not be obtained due to the light absorption by the p-side transparent electrode 216 even if the number of cycles of SiO₂/TiO₂ in the upper reflection film 220 is 20. To solve the problem, the film thickness of the p-side transparent electrode 216 is set to be smaller or equal to 30 nm and the number of cycles of SiO₂/TiO₂ in the upper reflection film 220 is set to more than or equal to 7, so that it is possible to form a low-loss upper reflection portion having a reflectivity of about 99%. Here, the upper reflection portion is used to refer to a structure of the upper reflection film 220 inclusive of the p-side transparent electrode 216.

According to the above structure, it is possible to realize an upper reflection portion and a lower reflection portion having a high reflectivity, and a higher light-confining effect can be obtained, and thus laser oscillation can be ensured.

### Variation 1 of Embodiment 2

Variation 1 of Embodiment 2 of the present invention will be described below with reference to the drawings.

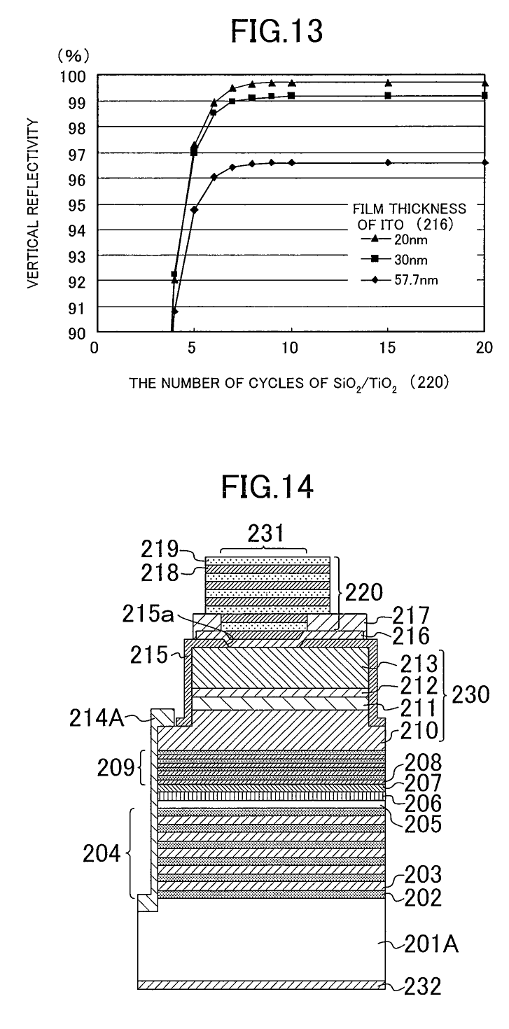

FIG. 14 shows a cross sectional configuration of a surface emitting laser device of Variation 1 of Embodiment 2 of the present invention. In FIG. 14, the same components of those of FIG. 10B are indicated by the same numerals and descriptions thereof are omitted.

As shown in FIG. 14, the surface emitting laser device of Variation 1 uses silicon (Si) having conductivity as a substrate 201A. Moreover, the n-side electrode formed on the exposed portion of the n-type cladding layer 210 is extended as an n-side electrode wire 214A to an exposed portion of an upper surface of the substrate 201A to connect the R-type cladding layer 210 and the substrate 201A electrically. Here, the side surface of the n-type cladding layer 210, and side surfaces the lower reflection film 209, the semiconductor thin film 206, the PSG film 205, and the multilayer DBR mirror 204 under the n-type cladding layer 210 corresponding to the exposed portion of the substrate 201A are selectively removed.

Moreover, on a surface of the substrate 201A opposite to the multilayer DBR mirror 204, a back surface electrode 232 made of, for example, aluminum (Al) having good ohmic characteristics is provided.

With this structure, the surface emitting laser device of Variation 1 allows electrons to be supplied from the back surface electrode 232 to the n-type cladding layer 210 via the substrate 201A having conductivity and the n-side electrode wire 214A. Therefore, since it is not necessary to connect the n-side electrode wire 214A to a connection wire or the like, the area of the n-side electrode can be reduced. That is, in the present variation, it is possible to reduce the chip size of the surface emitting laser device, and thus a low cost surface emitting laser device can be realized.

Moreover, the surface emitting laser device of Variation 1 can release heat generated during the operation via the n-side electrode wire 214A to the substrate 201A, and thus a surface emitting laser device having high reliability and formed of a nitride semiconductor can be obtained.

### Variation 2 of Embodiment 2

Variation 2 of Embodiment 2 of the present invention will be described below with reference to the drawings.

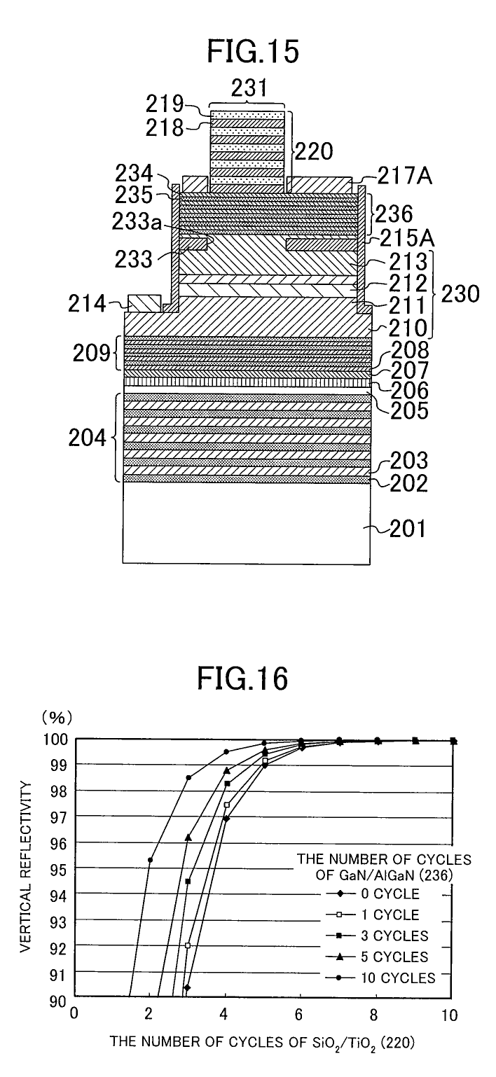

FIG. 15 shows a cross sectional structure of a surface emitting laser device of Variation 2 of Embodiment 2 of the present invention. In FIG. 15, the same components as those of FIG. 10B are indicated by the same numerals and descriptions thereof are omitted.

As shown in FIG. 15, the surface emitting laser device of Variation 2 is selectively provided with a current confinement layer 233 instead of the current confinement layer 215. The current confinement layer 215 is made of SiO₂ selectively covering the side surface and part of the upper surface of the p-type cladding layer 213 of surface emitting laser device of Embodiment 2. The current confinement layer 233 is made of SiO₂ having an opening 233a in an upper portion of the p-type cladding layer 213 and having a thickness of, for example, 100 nm.

Moreover, in Variation 2, a second upper reflection film 236 is provided over the p-type cladding layer 213. Using the current confinement layer 233 as a growth mask in MOCVD, the second upper reflection film 236 is formed of a layered film (semiconductor DBR mirror) including at least a pair of third nitride semiconductor films 234 made of p-type GaN and fourth nitride semiconductor films 235 made of p-type Al_{0.3}Ga_{0.7}N which are alternately stacked.

Here, the upper reflection film 220 (hereinafter, in Variation 2, referred to as first upper reflection film) made of SiO₂/TiO₂ is provided on the second upper reflection film 236 over the opening 233a of the current confinement layer 233 without providing the p-side transparent electrode 216. Moreover, on the second upper reflection film 236 around the first upper reflection film 220, a p-side electrode 217A made of palladium (Pd)/platinum (Pt)/gold (Au) is provided.

A protection layer 215A made of SiO₂ is provided on surfaces of the second upper reflection film 236, the p-type cladding layer 213 including the current confinement layer 233, the MQW active layer 212, and the electron overflow suppression layer 211 and on the etched surface of the n-type cladding layer 210.

It is to be noted that the current confinement layer 233 may be formed in the p-type cladding layer 213 or in the n-type cladding layer 210. In this structure, since a current injected in the pn junction diode structure 230 flows only directly under the exit region 231 and a light-emission region is restricted, the current value of an oscillation threshold current can be lowered due to a high light-confining effect.

Moreover, if the multilayer DBR mirror 204 made of SiO₂/TiO₂ is provided on the substrate 201, stress occurs, so that cracks are likely to occur. To solve the problem, in Embodiment 2, the PSG film 205 is formed between the nitride semiconductor and the substrate 201. With this structure, the softening point of the PSG film 205 becomes lower than a crystal growth temperature of the nitride semiconductor. Therefore, it is possible to relieve stress due to the difference between the thermal expansion coefficient of the pn junction diode structure 230 inclusive of the second upper reflection film 236 and the lower reflection film 209 and the thermal expansion coefficient of the substrate 201, the pn junction diode structure 230 being formed of the nitride semiconductor. As a result, occurrences of cracks in the nitride semiconductor can be suppressed.

That is, according to the nitride semiconductor light emitting device of the present invention, the critical film thickness in which cracks occur in the nitride semiconductor can be increased compared to the conventional configuration. According to the present variation, the second upper reflection film 236 having p-type GaN/p-type AlGaN can be formed without causing cracks. Here, each of the third nitride semiconductor film 234 made of p-type GaN and the fourth nitride semiconductor film 235 made of p-type AlGaN is formed to have a film thickness of λ/4n (where n is the refractive index of GaN or AlGaN) with respect to the emitted light wavelength of λ, i.e. designed such that a high reflectivity with respect to the emitted light wavelength can be obtained. Specifically, with respect to the emitted light wavelength of 470 nm, the p-type GaN has a thickness of 47.8 nm and the p-type Al_{0.3}Ga_{0.7}N has a thickness of 52.6 nm.

FIG. 16 shows the relationship between (i) the number of cycles of SiO₂/TiO₂ constituting the upper reflection film 220 and the number of cycles of p-type GaN/p-type AlGaN constituting the second upper reflection film 236 and (ii) the vertical reflectivity with respect to emitted light coming from the pn junction diode structure 230 of the surface emitting laser device of Variation 2 of Embodiment 2 of the present invention and having a wavelength of 470 nm. As can be seen from FIG. 16, as the number of cycles of p-type GaN/p-type AlGaN in the second upper reflection film 236 increases, the reflectivity increases. However, since the difference between the refractive indices of GaN and AlGaN is small, the change in reflectivity is also small.

Therefore, to set the reflectivity of the upper reflection portion including the first upper reflection film 220 and the second upper reflection film 236 to about 99%, it is necessary to set the number of cycles of SiO₂/TiO₂ in the first upper reflection film 220 to more than or equal to 5 regardless of the number of cycles of p-type GaN/p-type AlGaN in the second upper reflection film 236.

Moreover, since the upper reflection portion of the present variation does not include material causing optical loss such as the p-side transparent electrode made of ITO, it is possible to reduce the current value of the threshold current of the laser oscillation.

Moreover, in the present variation, the current confinement layer 233 is not formed on an upper surface of the second upper reflection film 236 but in the nitride semiconductor. Therefore, it is possible to increase the area where the second upper reflection film 236 and the p-side electrode 217A are in contact with each other. In this structure, series resistance of the nitride semiconductor is reduced, which reduces the operating voltage and the amount of generated heat, so that it is possible to obtain a surface emitting laser device having high reliability and formed of a nitride semiconductor.

As described above, the nitride semiconductor light emitting device of the present invention and method for fabricating the same reduce the absorption of emitted light by the substrate for crystal growth, thereby improving the light extraction efficiency of the nitride semiconductor light emitting device, and are applicable to a high-luminance nitride semiconductor light emitting device or the like for various display devices or illuminations.

What is claimed is:

1. A nitride semiconductor light emitting device comprising:
a dielectric layered film over a substrate, the dielectric layered film being formed by stacking a plurality of dielectric films having different compositions;
a semiconductor thin film formed of a single crystal over the dielectric layered film; and
a pn junction diode structure over the semiconductor thin film, the pn junction diode structure being formed of a nitride semiconductor.

2. The nitride semiconductor light emitting device of claim 1, wherein the semiconductor thin film is made of silicon, silicon carbide, or gallium nitride.

3. The nitride semiconductor light emitting device of claim 1, wherein
part of the dielectric layered film is formed by alternately stacking first dielectric films and second dielectric films having different compositions; and
each of the first dielectric films and the second dielectric films has a film thickness of ¼ of an optical wavelength corresponding to an emitted light wavelength.

4. The nitride semiconductor light emitting device of claim 1, wherein
the dielectric layered film partially includes a glass-like film, and
a temperature for liquefaction of the glass-like film is lower than a temperature for liquefaction of silicon oxide.

5. The nitride semiconductor light emitting device of claim 4, wherein the glass-like film includes at least one of PSG (Phospho Silicate Glass) and BPSG (Boro Phospho Silicate Glass).

6. The nitride semiconductor light emitting device claim 1, wherein the dielectric layered film has a conductive member made of a metal, the conductive member passing through the dielectric layered film and being electrically connected to the substrate.

7. The nitride semiconductor light emitting device of claim 1, further comprising a first reflection film over a surface of the pn junction diode structure opposite to the dielectric layered film, the first reflection film facing the dielectric layered film.

8. The nitride semiconductor light emitting device of claim 1, wherein on a side surface of the dielectric layered film, electrode wiring electrically connecting the pn junction diode structure with the substrate is provided.

9. The nitride semiconductor light emitting device of claim 7, wherein
the first reflection film is formed by alternately stacking third dielectric films and fourth dielectric films having different compositions, and
each of the third dielectric films and the fourth dielectric films has a film thickness of ¼ of an optical wavelength corresponding to an emitted light wavelength.

10. The nitride semiconductor light emitting device of claim 9, wherein
part of the first reflection film is formed of a conductive film being transparent to the emitted light wavelength, and
part of the conductive film is in contact with the nitride semiconductor.

11. The nitride semiconductor light emitting device of claim 7, wherein
the first reflection film is formed by alternately stacking first nitride semiconductor films and second nitride semiconductor films having different compositions, and
each of the first nitride semiconductor films and the second nitride semiconductor films has a film thickness of ¼ of an optical wavelength corresponding to an emitted light wavelength.

12. The nitride semiconductor light emitting device of claim 11, wherein
the first nitride semiconductor film is made of GaN, and
the second nitride semiconductor film is made of AlₓIn_{y}Ga_{1-x-y}N (where 0≦x≦1, 0≦y≦1, and x+y<1).

13. The nitride semiconductor light emitting device of claim 11, further comprising a second reflection film over the first reflection film,
wherein the second reflection film is formed by alternately stacking third dielectric films and fourth dielectric films having different compositions, and
each of the third dielectric films and the fourth dielectric films has a film thickness of ¼ of the optical wavelength corresponding to the emitted light wavelength.

14. The nitride semiconductor light emitting device of claim 11, further comprising a current confinement layer in the pn junction diode structure under the first reflection film, the current confinement layer having an opening which opens in a direction vertical to a substrate surface.

15. The nitride semiconductor light emitting device of claim 14, wherein the current confinement layer is covered with GaN.

16. The nitride semiconductor light emitting device of claim 7, further comprising a third reflection film between the dielectric layered film and the pn junction diode structure,
wherein the third reflection film is formed by alternately stacking third nitride semiconductor films and fourth nitride semiconductor films having different compositions, and
each of the third nitride semiconductor films and the fourth nitride semiconductor films has a film thickness of ¼ of an optical wavelength corresponding to an emitted light wavelength.

17. The nitride semiconductor light emitting device of claim 7, wherein the semiconductor thin film is transparent to an emitted light wavelength.

18. The nitride semiconductor light emitting device of claim 17, wherein the semiconductor thin film is formed of a mixed crystal of silicon carbide and aluminum nitride.

19. The nitride semiconductor light emitting device of claim 7, wherein
the pn junction diode structure partially forms a resonator, and
the resonator is in contact with a p-side electrode or an n-side electrode.

20. A method for fabricating a nitride semiconductor light emitting device comprising the steps of:
(a) alternately stacking a plurality of dielectric films having different compositions over a substrate to form a dielectric layered film;
(b) bonding a semiconductor thin film formed of a single crystal to the dielectric layered film; and
(c) forming a pn junction diode structure formed of a nitride semiconductor over the semiconductor thin film.

21. The method of claim 20, wherein each of the dielectric films has a film thickness of ¼ of an optical wavelength corresponding to an emitted light wavelength.

22. The method of claim 20, wherein step (b) includes:
a first step of preparing a semiconductor substrate having a hydrogen injection region where ions of hydrogen are injected to a predetermined depth in a whole area of a principal surface of the semiconductor substrate;
a second step of bonding the principal surface of the semiconductor substrate to the dielectric layered film; and
a third step of heating the semiconductor substrate bonded to the dielectric layered film to peel off the semiconductor substrate at the hydrogen injection region.

23. The method of claim 20, wherein the semiconductor thin film is made of silicon.

24. The method of claim 22, wherein
the semiconductor substrate is made of silicon; and
the first step includes subjecting the semiconductor substrate to a hydrocarbon gas such that a region of the semiconductor substrate for forming the semiconductor thin film is converted to silicon carbide.

25. The method of claim 20, wherein
step (a) includes forming a glass-like film in a lower or upper portion of the dielectric layered film, and
step (c) includes performing crystal growth of the nitride semiconductor at a temperature higher than a temperature for liquefaction of the glass-like film.

26. The method of claim 25, wherein the glass-like film includes at least one of PSG (Phospho Silicate Glass) and BPSG (Boro Phospho Silicate Glass).
